(19) United States
(12) Patent Application Publication
(10) Pub. No.: US 2008/0191788 A1
(43) Pub. Date: Aug. 14, 2008

(54) SOI MOSFET DEVICE WITH ADJUSTABLE THRESHOLD VOLTAGE

(75) Inventors: Xiangdong Chen, Poughquag, NY (US); Haining S. Yang, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/672,592

(22) Filed: Feb. 8, 2007

(51) Int. Cl. G05F 1/10; H01L 21/336

(52) U.S. Cl. 327/537; 438/157; 257/E21.411

(57) ABSTRACT

An SOI semiconductor device includes a silicon semiconductor layer divided into an FET region with source, channel, and drain regions therein formed on a BOX layer, with a switch region next to the FET region; and a contact region next to the switch region distal from the FET region. The FET region has a greater thickness than the switch region. A conformal gate dielectric layer covers the FET region and the switch. A dual function gate electrode formed over the gate dielectric layer includes an FET portion above the FET region and an auxiliary gate portion extending therefrom above the switch region. A contact is formed reaching through the gate dielectric layer into electrical and mechanical contact with the contact region. The switch varies the depth of the depletion region to open and close current flow between the channel of the FET device and the contact region to suppress subthreshold leakage current.

### BACKGROUND OF THE INVENTION

This invention relates to semiconductor devices and methods of manufacture thereof. More particularly this invention relates to Field Effect Transistor (FET) devices and methods of manufacture thereof.

Currently power consumption has become a great concern for those designing VLSI circuits. In the past few years, many portable devices and wireless application systems have emerged and such products have become a principal driver of industry growth. The demand for portability of these systems limits their battery size which places severe constraints on the power consumption. Even for the non-portable devices, as the sizes of transistors are scaled down, with increasing circuit speed and density the result is that the amount of power consumption has become a critical parameter. To produce a satisfactory level of circuit speed it is important to maintain a sufficient level of gate over-drive voltage V_{gt} which is defined as gate to source voltage (V_{gs}) minus the threshold voltage Vₜ, i.e. V_{gt}=V_{gs}−Vₜ. The most common approach to reduction of power consumption is the scaling of the power supply voltage V_{dd} while still maintaining a high enough level of gate over-drive voltage V_{gt} without sacrificing circuit speed. However, the threshold voltage Vₜ cannot be scaled down by the same amount as the power supply voltage Vdd because of the problem of sub-threshold leakage current (I_{leakage}) and the low limit for the sub-threshold swing. So, for a standard Metal Oxide Semiconductor Field Effect Transistor (MOSFET) or more generally a Metal Insulator Semiconductor Field Effect Transistor (MISFET), it is increasingly challenging to scale down the power supply voltage V_{dd}, to improve the circuit speed, and to limit the subthreshold leakage current (I_{leakage}) simultaneously.

Dynamic Threshold Voltage MOSFET (DTMOSFET), as seen in (Assaderagi et al., IEEE TED, p.414, 1997; and Hu et al. U.S. Pat. No. 5,559,368 entitled “Dynamic Threshold Voltage MOSFET Having Gate to Body Connection for Ultra-Low Voltage Operation” has been proposed and developed to realize a high performance transistor by connecting the gate to the silicon well. DTMOSFET can achieve both high drive current at “on” state and low off-state leakage current at the same time. In the off-state, Vgs=Vbs=0V, the transistor has a high threshold voltage. In the on-state, Vgs=Vds=Vbs, the transistor has low threshold voltage because gate bias is applied to the body. There is one disadvantage for this device. Because gate bias is connected to the body, the leakage current of forward biased p-n junction at the source increases dramatically when the supply voltage higher than 0.7V. Thus, the supply voltage must be smaller than 0.7V.

Commonly assigned U.S. Pat. No. 6,664,598 of Dennard et al. entitled “Polysilicon Back-Gated SOI MOSFET for Dynamic Threshold Voltage Control” describes a Silicon On Insulator (SOI) device with a body region which comprises a doped silicon film. Unlike conventional SOI devices there are dual, front, and back gates, i.e. gate electrodes. The front and back gates are separated by the sandwich of a front gate dielectric above the body region and back gate dielectric below the body region. The Dennard patent '598 teaches that the polysilicon back-gate is capable of controlling the threshold voltage Vₜ of the front-gate which comprises a conventional polysilicon gate, because the surface potentials at the front and back interfaces are strongly coupled to each other and capacitively coupled to the front and back-gate dielectrics, respectively. Therefore, the potential through the silicon film, and hence the charge, is determined by the bias conditions on both the front and back-gates. In other words, the back-gate controls the threshold voltage Vₜ of the front-gate device.

Commonly assigned U.S. Pat. No. 5,770,881 of Pelella et al. entitled “SOI FET design to reduce transient bipolar current” describes producing a gap between a source and/or drain region of a silicon-on-insulator (SOI) FET transistor which is less than the thickness of a depletion region normally surrounding the source and/or drain region, preferably at zero volts bias.

Assaderagi et al., IEEE TED, p.414, 1997 describes a Dynamic Threshold Voltage MOSFET (DT-MOSFET), e.g. an Insulated Gate Field Effect Transistor (IGFET) such as a MOSFET which is operable at voltages of 0.6 volt or less. The threshold voltage of the transistor is reduced to zero volts or less by interconnecting i.e. short circuiting, the gate electrode to the silicon well by connecting the gate contact to the device body in which the voltage controlled channel is located. A higher power supply voltage is employed by interconnecting the gate and device body through a smaller MOSFET. The DT-MOSFET device achieves both a high drive current at on-state and low off-state leakage current at the same time. In the off-state, the gate to source voltage V_{gs} is equal to the body to source voltage V_{bs} with both of them being equal to zero Volts (0V). The transistor has a high threshold voltage. In the on-state, the gate to source voltage V_{gs} is equal to the drain to source voltage V_{ds} which is equal to the body to source voltage V_{bs} (i.e. V_{gs}=V_{ds}−V_{bs}.) The transistor has a low threshold voltage Vₜ because gate bias V_{g} is applied to the body of the transistor. However, there is a significant disadvantage for this device, which is that because the gate bias V_{g} is connected to the body, the leakage current of forward biased p-n junction at the source increases dramatically when the supply voltage rises to a level higher than 0.7V. Therefore, the power supply voltage V_{dd} must be smaller than 0.7V.

U.S. Pat. No. 7,061,050 of Fazan et al. entitled “Semiconductor Device Utilizing Both Fully and Partially Depleted Devices” describes a semiconductor device such as a MOSFET device formed on a semiconductor substrate. An energy band modifying means covered by an insulating layer is located below the body of the MOSFET in the form of a “silicon box region” of p-type silicon which is highly doped compared with the body of the FET, but less highly doped than the corresponding source/drain regions. A semi-conductor layer has source/drain regions formed therein to define bodies of respective FETs. The “silicon box region” is more heavily doped than the adjacent body, but less highly doped than the corresponding source/drain regions, and modifies the valence and/or conduction band of the body to increase the amount of electrical charge which can be stored in the body. By applying a negative voltage to “box region”, typically in the region of −20V for a layer of thickness 400 nm, it is possible by means of the potential difference between gate and “box region” to form a neutral zone in the body. Thus, it is possible to generate, store and eliminate an electric charge in the neutral zone. The voltage necessary to create the neutral zone is reduced if the thickness of the layer is reduced.

Commonly assigned U.S. Pat. No. 7,045,873 of Chen et al. entitled “Dynamic Threshold Voltage MOSFET on SOI” describes provision of a body control contact adjacent a transistor and between the transistor and a contact to the substrate or well in which the transistor is formed allows connection and disconnection of the substrate of the transistor to and from a zero (ground) or substantially arbitrary low voltage in accordance with control signals applied to the gate of the transistor to cause the transistor to exhibit a variable threshold which maintains good performance at low supply voltages and reduces power consumption/dissipation which is particularly advantageous in portable electronic devices. Floating body effects (when the transistor substrate in disconnected from a voltage source in the “ON” state) are avoided since the substrate is discharged when the transistor is switched to the “OFF” state. The transistor configuration can be employed with both n-type and p-type transistors which may be in complementary pairs.

Commonly assigned U.S. Pat. No. 7,102,914 of Chen et al. entitled “Gate controlled floating well vertical MOSFET” describes a transistor structure for a DRAM cell including two deep trenches. One trench includes a vertical storage cell for storing data. The second trench includes a vertical control cell for controlling the p-well voltage, which, in effect, places part of the p-well in a floating condition thus decreasing the threshold voltage Vₜ as compared to when the vertical pass transistor is in an off-state. This enables the transistor to exhibit increased gate overdrive voltage gate over-drive voltage V_{gt} and drive current during the presence of an active wordline voltage commonly applied to the gates of both the storage cell and the control cell.

U.S. Pat. No. 6,489,655 of Doyle et al. entitled “Integrated Circuit with Dynamic Threshold Voltage” describes an integrated circuit. The integrated circuit includes substrate on which a first insulating layer is formed. A body strap of a first conductivity type and an adjacent second insulating layer are formed on the first insulating layer. A film is formed on the second insulating layer. A gate electrode is formed on the film. Several doped regions of a second conductivity type are formed within the film extending from the surface of the film to the surface of the second insulating layer. The doped regions have junctions, with each spaced from the body strap by at least about 500 Å.

U.S. Pat. No. 6,166,584 of De entitled “Forward Biased MOS Circuits” describes a semiconductor circuit including one or more transistors each having a body and one or more a variable voltage source to selectively provide a forward bias to the bodies at certain times and to provide a non-forward bias to the body at other times. The semiconductor circuit includes voltage control circuitry to control whether the variable voltage source provides the forward bias or the non-forward bias. In some embodiments, the voltage control circuit controls the variable voltage source providing a forward bias during an active mode of the transistors and the non-forward bias is provided during a standby mode of the transistors.

### SUMMARY OF THE INVENTION

An object of this invention is to scale down the power supply, voltage, improve the circuit speed, and limit the leakage current simultaneously.

Another object of this invention is to solve the problem of limited the supply voltage because of concerns about leakage while at the same time maintaining the benefits of DTMOSFET technology.

In accordance with this invention a device and a method of manufacture thereof are provided whereby a MOSFET device formed in an SOI structure includes a conventional gate electrode and an integral auxiliary gate. A depletion switch is formed by an auxiliary gate and a thinner region of the silicon layer located below the auxiliary gate. The depletion switch controls the connection of a body contact to the channel of the MOSFET as a function of gate voltage. The depletion switch thereby isolates the body of the MOSFET from the body contact region when the gate electrode is in the ON state with the isolation being provided by maintaining a fully depleted region under the switch formed by auxiliary portion of the gate electrode and the thinner region of the SOI region. Thus the P-well is disconnected from the body contact and is in a floating state when the MOSFET is ON. On the other hand, when the MOSFET is OFF the region of the body under the auxiliary gate is not fully depleted and the body of the FET is connected to a P-well contact region. In the OFF state, a negative body bias Vpw can be applied to the P-well contact region which is connected to the channel of the MOSFET through the depletion switch. The structure suppresses subthreshold leakage current.

In accordance with this invention, a semiconductor device includes a conductive contact, an FET device, and a switch located therebetween. A semiconductor layer is formed over a top surface of a dielectric layer, with the semiconductor layer being divided into a contact region, an FET region having a first thickness, and a switch region having a second thickness less than the first thickness. A gate dielectric layer is formed on an upper surface of the semiconductor layer over the FET region and over the switch region. An FET device including, a source region, a channel region and a drain region is formed in the FET region of the semiconductor layer, and an FET gate electrode is formed on top of the gate dielectric layer above the channel. The switch is juxtaposed with the FET device and includes an auxiliary gate electrode formed on the top surface of the gate dielectric layer above the switch region with the auxiliary gate electrode being connected to the FET gate electrode. The conductive contact is connected to the contact region formed in the semiconductor layer juxtaposed with the switch region and distal from the FET region.

Preferably, the switch region is formed in a recess in the upper surface of the semiconductor layer and surfaces of the recess are covered by the gate dielectric which reaches down into the recess. It is also preferred that the auxiliary gate electrode reaches down into the recess above the switch region juxtaposed with the FET region; that the contact region is juxtaposed with the switch region on an opposite side thereof from the FET region; and that an appropriate (positive N-well or a negative P-well) voltage V_{pw} is connected to the conductive contact for supply to the FET region when the switch is closed. Preferably, STI regions extend through the semiconductor layer to the top surface of the dielectric layer thereby defining a well in the semiconductor layer on either side of the FET region and the switch region. It is preferred that a contact is formed in the contact region juxtaposed with the switch region on the opposite side thereof from the FET region.

In accordance with another aspect of this invention, a method is provided for forming a semiconductor device including an FET device a contact, and a switch therebetween. Form a semiconductor layer over a top surface of a dielectric layer with the semiconductor layer being divided into a contact region, an FET region having a first thickness, and a switch region having a second thickness less than the first thickness. Form a conformal gate dielectric layer covering the FET region and the switch region. Form an extended gate electrode over the gate dielectric layer including an FET gate electrode located above the FET region and an auxiliary gate electrode extending from the FET gate electrode over the switch region. Form an FET device with a source region and a drain region in the FET region juxtaposed with the gate electrode, and form a contact reaching into electrical and mechanical contact with the contact region aside from the switch and distal from the FET device, whereby the auxiliary switch gate is adapted to open and close the switch in the switch region as a function of voltage applied thereto, thereby suppressing subthreshold leakage current.

Preferably, the switch region is formed in a recess in the upper surface of the semiconductor layer and surfaces of the recess are covered by the gate dielectric which reaches down into the recess. It is also preferred that the auxiliary gate electrode reaches down into the recess above the switch region juxtaposed with the FET region; that the contact region is juxtaposed with the switch region on an opposite side thereof from the FET region; and that an appropriate (positive N-well or a negative P-well) voltage V_{pw} is connected to the conductive contact for supply to the FET region when the switch is closed. Preferably, STI regions extend through the semiconductor layer to the top surface of the dielectric layer thereby defining a well in the semiconductor layer on either side of the FET region and the switch region. It is preferred that a contact is formed in the contact region juxtaposed with the switch region on the opposite side thereof from the FET region.

The invention and objects and features thereof will be more readily apparent from the following detailed description and appended claims when taken with the drawings.

### BRIEF DESCRIPTION OF THE DRAWINGS

The foregoing and other aspects and advantages of this invention are explained and described below with reference to the accompanying drawings, in which:

FIGS. 1A-11A are plan views of stages of manufacture of an NMOSFET type of MISFET transistor being manufactured in accordance with the method of this invention.

FIGS. 1B-11B are cross-sectional, elevational views of the NMOSFET, MISFET device of corresponding ones of FIGS. 1A-11A taken along line B-B′ therein.

FIG. 12 is a flow chart of the significant steps of performing the method of forming the MISFET device of FIGS. 11A, 11B.

FIG. 13A is a schematic electrical circuit diagram of the MISFET device of FIGS. 11A and 11B when operating in the OFF state.

FIG. 13B is a schematic electrical circuit diagram of the MISFET transistor of FIGS. 11A and 11B when operating in the ON state.

FIG. 14A is a cross-sectional, elevational view of the MISFET transistor of FIGS. 11A and 11B when operating in the OFF state.

FIG. 14B is a cross-sectional, elevational view of the MISFET transistor of FIGS. 11A and 11B when operating in the ON state.

FIG. 15A is a plan view of a PMOSFET type of MISFET transistor manufactured in accordance with the method of this invention. FIG. 15B—is a cross-sectional, elevational view of the device of FIG. 15A taken along line B-B′ therein.

### DESCRIPTION OF THE PREFERRED EMBODIMENT

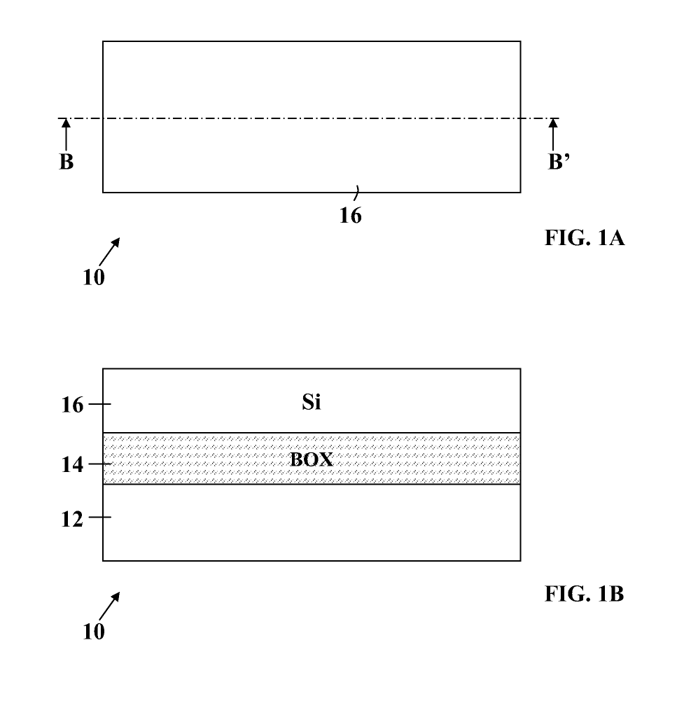

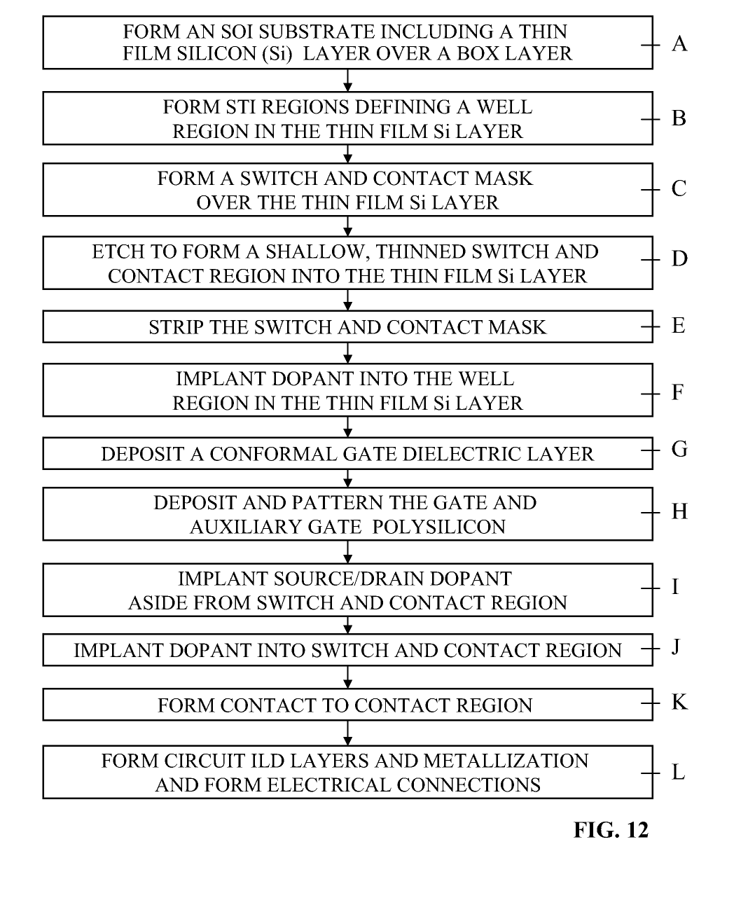

FIG. 1A shows a plan view of an early stage in the manufacturing process after step A in FIG. 12 in which an SOI NMOSFET type of MISFET semiconductor transistor device 10 has been formed in accordance with the method of this invention. FIG. 1B is a cross-sectional, elevational view of the SOI MISFET device 10 of FIG. 1A taken along line B-B′ therein. FIGS. 1A and 1B illustrate the result of performance of the step A in FIG. 12, which is to form a thick substrate 12 with a Buried Oxide (BOX) layer 14 formed thereover. In turn a thin film, monocrystalline, silicon (Si) layer 16 has been formed on the top surface of the BOX layer 14. The thin film, monocrystalline, silicon (Si) layer 16 has a thickness of “h1” which is within the conventional range of thicknesses of typical SOI silicon layers.

Referring to FIG. 1B, the MISFET device 10 is formed on the thick substrate 12 which may be composed of silicon semiconductor material or alternatively may be composed of silicon germanium (SiGe) or gallium arsenide (GaAs.) The BOX layer 14 generally comprising silicon oxide is formed on the top surface of the thick substrate 12. A relatively thin film, monocrystalline silicon layer 16 is formed on the top surface of the BOX layer 14. The thin film silicon layer 16 forms the top of the device 10 at this stage of the process, as shown by FIGS. 1A and 1B.

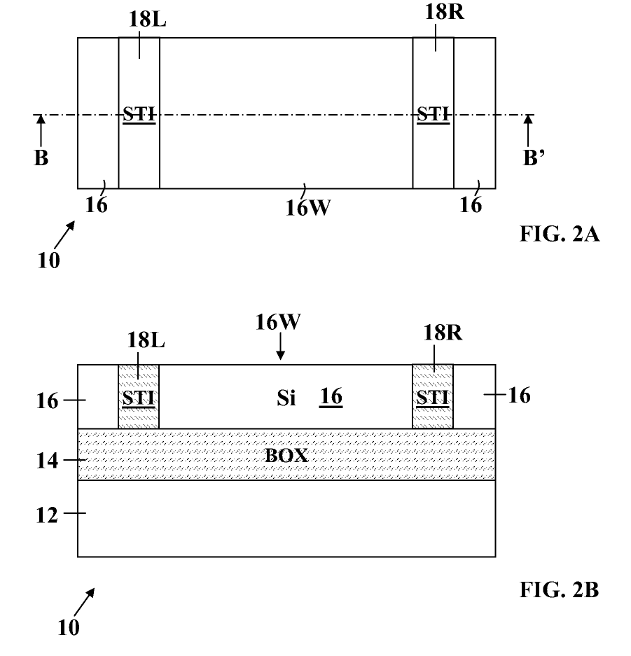

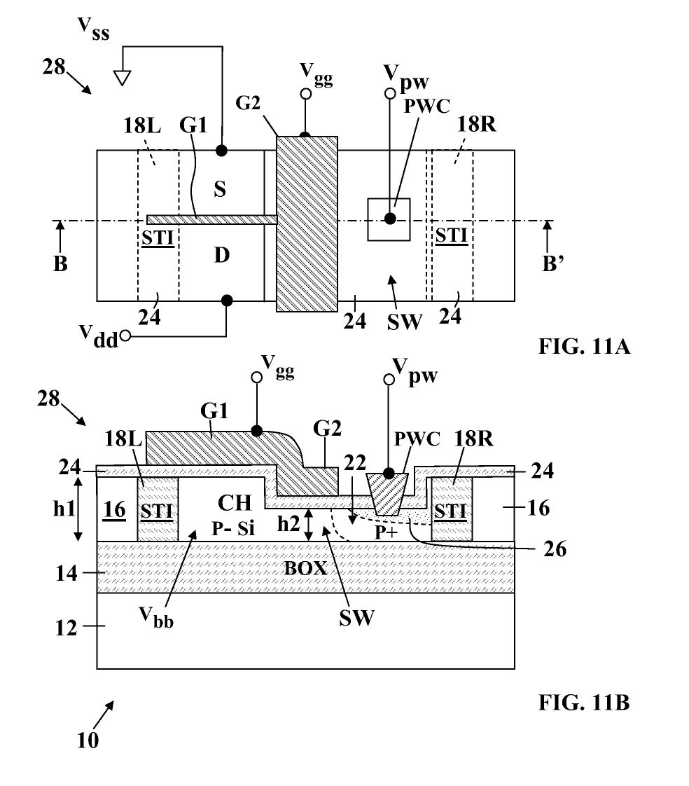

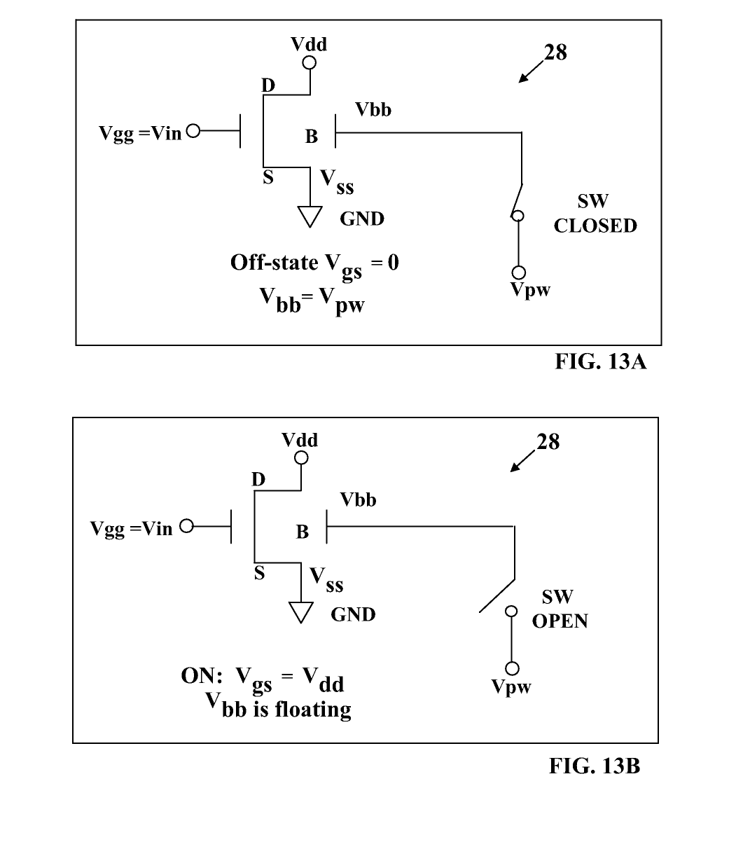

Referring to FIGS. 2A and 2B, the device of FIGS. 1A and 1B is shown after step B in FIG. 12 in which two Shallow Trench Isolation (STI) regions 18L on the left and 18R on the right have been formed in the monocrystalline thin film, silicon layer 16. The STI regions 18 extend through thin film, silicon layer 16 down to the top surface of the BOX layer 14 in the MISFET device 10. The STI regions 18 define the lateral boundaries of a well region 16W in layer 16 wherein an FET 28, a switch SW and a P-well contact PWC are to be formed as shown in FIGS. 11A and 11B (shown in schematic diagrams FIGS. 13A/13B). FIGS. 2A and 2B illustrate the result of performance of step B in FIG. 12 which is to form STI regions 18 defining the boundaries of the well region 16W in the thin film Si layer.

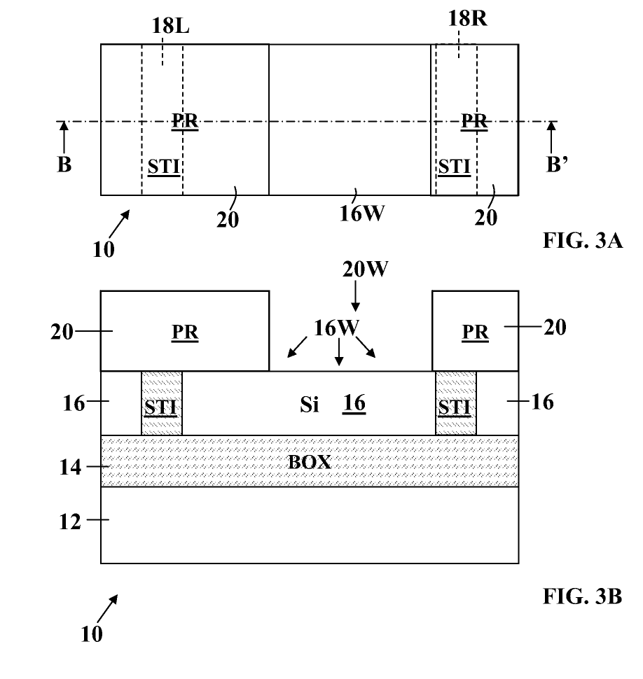

Referring to FIGS. 3A and 3B the device of FIGS. 2A and 2B is shown after step C in FIG. 12 in which a switch and contact mask 20 composed of photoresist (PR) or the like has been formed over the top surface of the silicon layer 16. A switch and contact window 20W has been formed extending down through switch and contact mask 20 down to surface of the thin film, silicon layer 16 in accordance with step C in FIG. 13. The mask and the window 20W are formed in accordance with well known photolithographic processing techniques. The switch and contact window 20W is spaced away from the left STI region 18L and extends approximately across to the right hand STI region 18R.

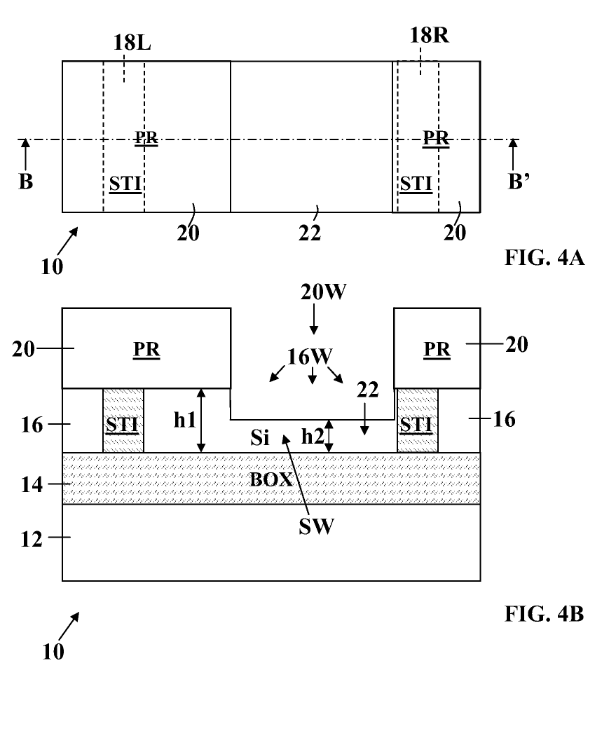

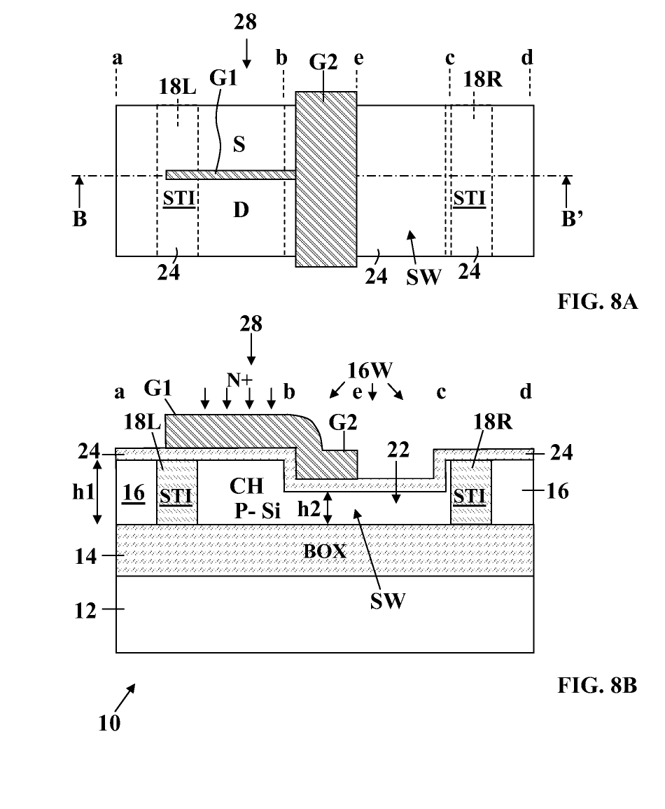

Referring to FIGS. 4A and 4B, the device of FIGS. 3A and 3B is shown after step D in FIG. 12 in which a thinner region including a switch region SW and an adjacent contact region 22 with a thickness of “h2” has been formed in the silicon layer 16 by etching through the switch and contact window 20W. An FET device 28 (shown in FIGS. 8A/8B et seq.) will be formed in the region with the greater “h1” thickness. The lesser thickness “h2” of the thinned, combined switch region SW and the adjacent contact region 22 is substantially less than the thickness “h1” of the layer 16; i.e. h2<<h1 for the purpose of modifying the relative depletion in the “h2” switch region SW with respect to the depletion in the “h1” region where the FET 28 is to be formed.

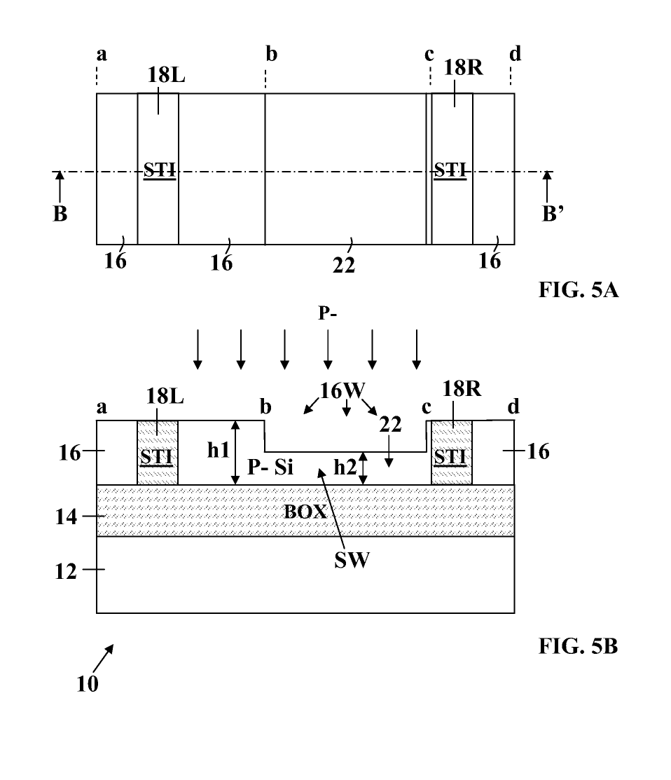

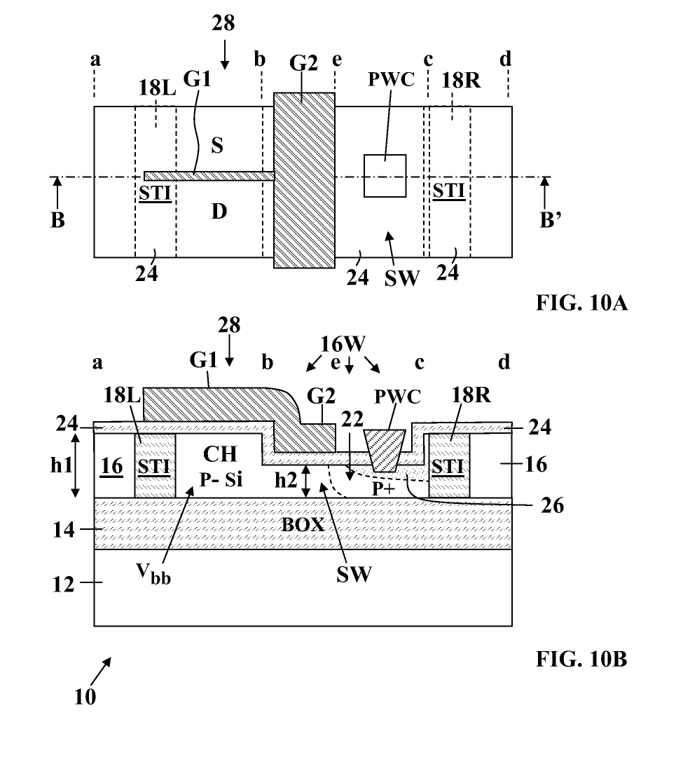

Referring to FIGS. 5A and 5B, the device of FIGS. 4A and 4B is shown after steps E and F in FIG. 12 in which the switch and contact mask 20 has been stripped from the device 10 and P− dopant has been implanted into the well region 16W including both the portion of the P-well region in which the FET 28 will be formed and the thinned, switch region where a switch SW will be formed and the contact region 22 where a P-well contact PWC will be formed as shown in FIGS. 10A/10B.

The STI region 18L is located between the points “a” and “b.” The FET 28 will be formed in the silicon layer 16 between the left STI region 18L and point “b.” The switch region SW and the contact region 22 will be formed in the shallow, thinner portion of silicon layer 16 between points “b” and “c.” The region to the right of the combination of the thinned, switch region SW and contact region 22 is located between points “c” and “d.”

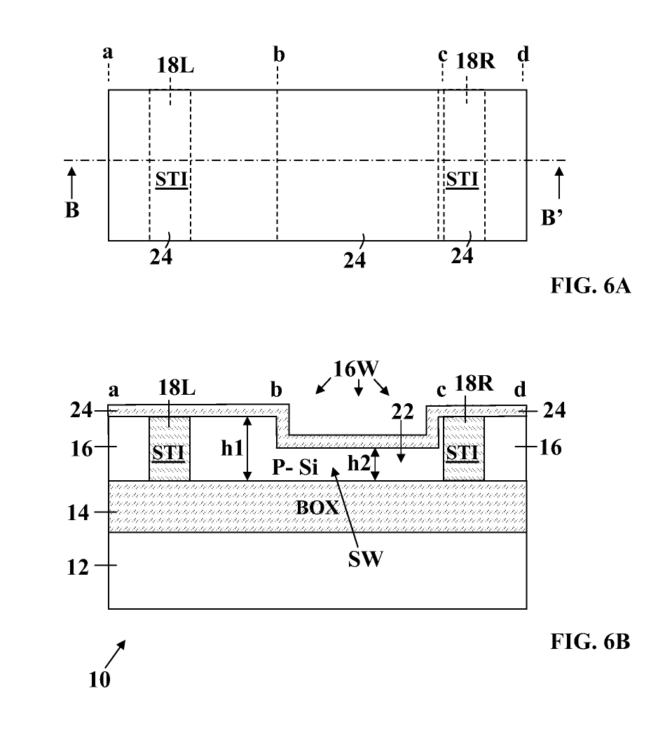

Referring to FIGS. 6A and 6B, the device of FIGS. 5A and 5B is shown after step G in FIG. 12 in which a conformal gate dielectric layer 24 has been formed covering the top surface of the device 10 including the top surface of the thin film silicon layer 16, as well as the STI regions 18 and the shallow, thinned, switch region SW and the contact region 22 in the P-well 16W.

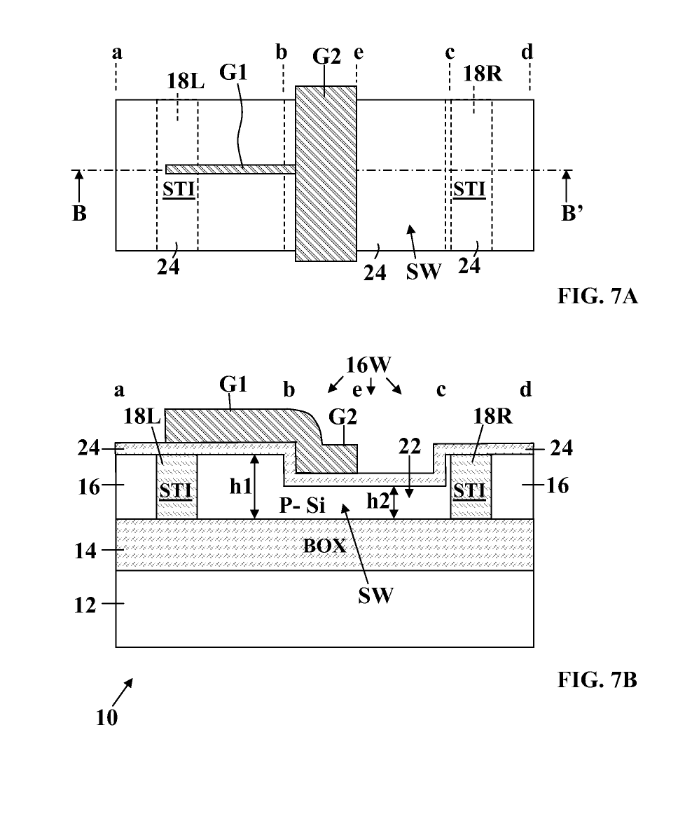

Referring to FIGS. 7A and 7B, the device of FIGS. 6A and 6B is shown after step H in FIG. 12 in which a gate polysilicon layer has been deposited upon the gate dielectric layer 24 and patterned into a gate electrode G1 and an auxiliary portion G2 of the gate electrode (hereinafter the auxiliary gate G2). The gate electrodes G1 and G2 are part of the same integral structure, but they perform complementary functions. The main gate electrode G1 (hereinafter the gate) extends from above a portion of the left STI region 18L to near point “b” which is the end of the region where the FET 28 is being formed. The auxiliary gate G2 extends just beyond point “b” to point “e” (in the direction of point “c”) across only a portion of the thinned switch region SW and contact region 22 in the P-well 16W leaving a gap between the edge thereof between point “e” and point “c” leaving room for formation of a P-well contact. The function of the auxiliary gate G2 is to provide a binary ON/OFF switch SW between points “b” and “c” of the body of the device 10 to suppress subthreshold leakage current through the body of the device 10.

Referring to FIGS. 8A and 8B, the device of FIGS. 7A and 7B is shown following performance of step 1 in FIG. 12 in which the source drain regions S/D are formed in the silicon layer 16 (aside from the P-well switch and contact region 22) between the left STI region 18L and point “b” by ion implantation with N+ dopant to form the FET 28 on either side of the gate electrode G1, with the channel region CH formed below the gate electrode G1.

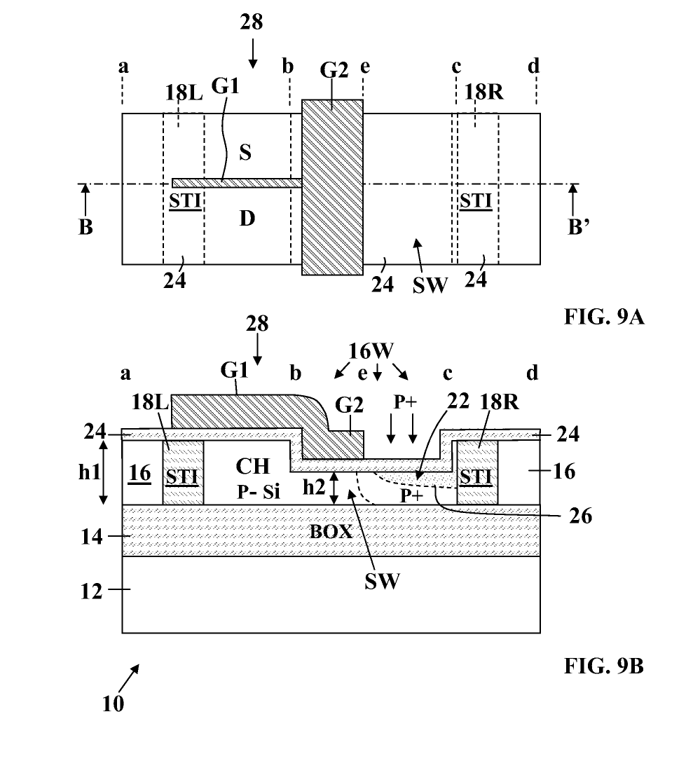

Referring to FIGS. 9A and 9B, the device of FIGS. 8A and 8B is shown after step J in FIG. 12 in which P+ dopant is implanted into the contact region 22 thereby forming a doped contact region 26 aside from the auxiliary gate G2, between points “e” and “d.”

Referring to FIGS. 10A and 10B, the device of FIGS. 9A and 9B is shown after step K in FIG. 12 in which the P-well contact PWC has been formed in and above the contact region 22 to provide an external connection to the P-well contact region 26 between the auxiliary gate G2 and the right STI region 18R.

Referring to FIGS. 11A and 11B, the device of FIGS. 10A and 10B is shown after step L in FIG. 12 in which a circuit has been formed with voltage sources connected to the device 10. The gates G1 and G2 are connected to the input voltage V_{gg}. The source region S is connected to reference potential Vₛₛ. The drain region D is connected to the power supply voltage V_{dd}. The P-well contract PWC is connected to the negative P-well voltage V_{pw}.

FIG. 13A is a schematic electrical circuit diagram of the MISFET device of FIGS. 11A and 11B when operating in the OFF state because G1/G2=0, the switch SW causing the switch SW to be CLOSED so V_{bb}=V_{pw}.

FIG. 13B is a schematic electrical circuit diagram of the MISFET transistor of FIGS. 11A and 11B when operating in the ON state because G1/G2= power supply voltage V_{dd} causing the switch SW to be OPEN so V_{bb} is floating.

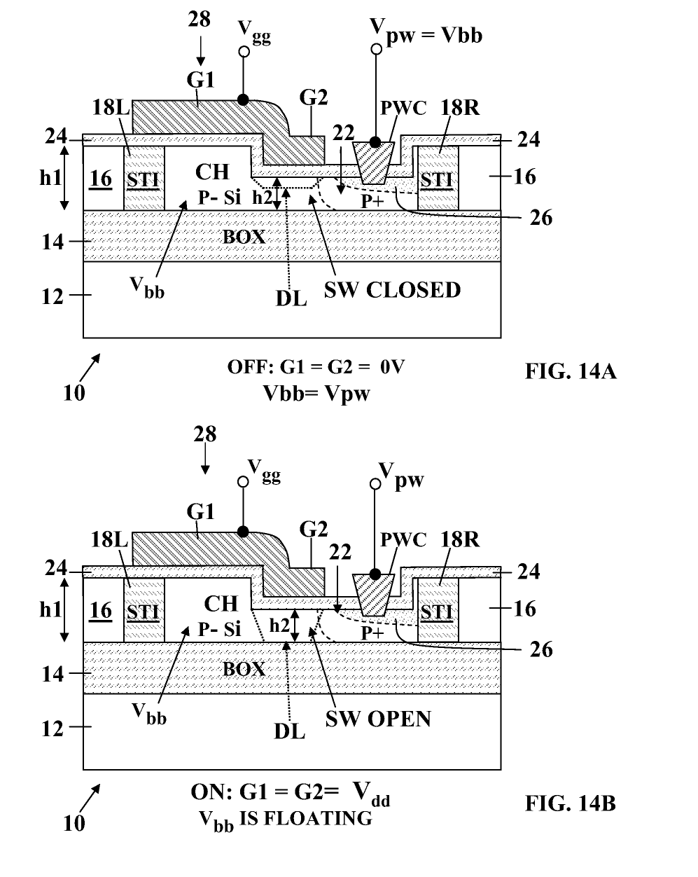

FIG. 14A is a cross-sectional, elevational view of the MISFET transistor of FIGS. 11A and 11B when operating in the OFF state corresponding to FIG. 13A.

FIG. 14B is a cross-sectional, elevational view of the MISFET transistor of FIGS. 11A and 11B when operating in the ON state corresponding to FIG. 13B.

### Alternative Embodiment

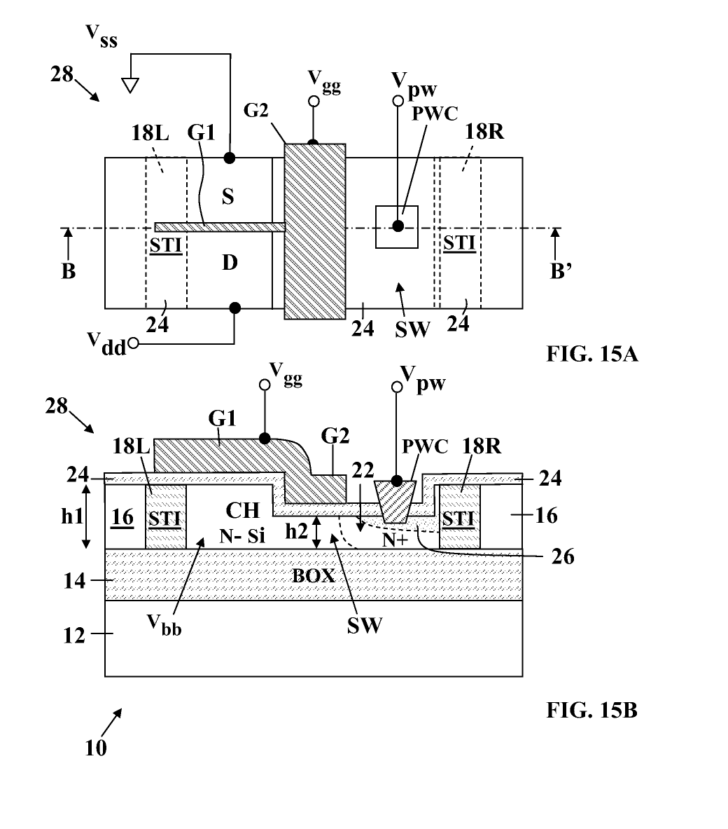

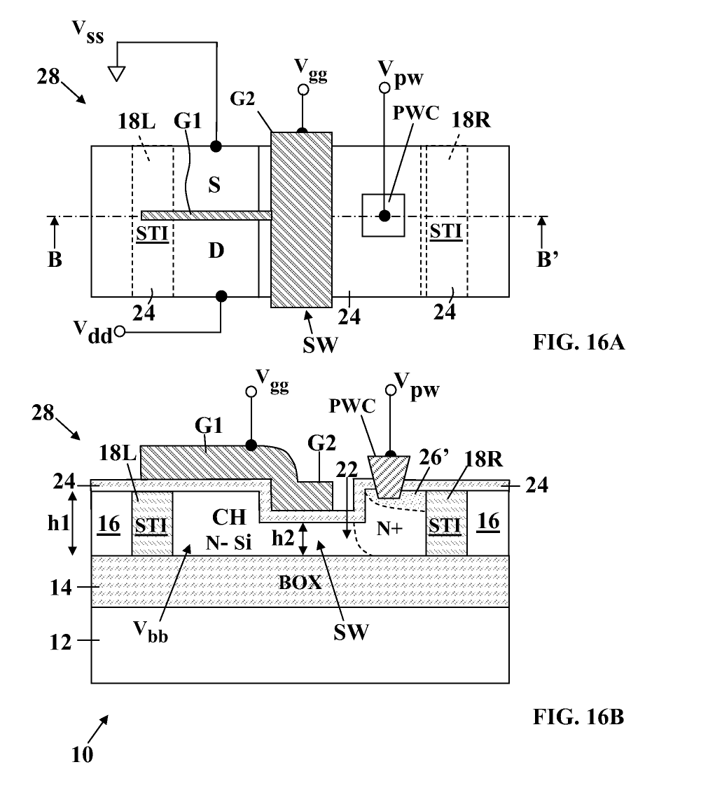

While the above described embodiment shows an implementation of the invention as a NMOSFET device, as will be obvious to those skilled in the art, the invention can be embodied as a PMOSFET device with an N well contact which is maintained at a positive voltage. FIG. 15A is a plan view of such a PMOSFET MISFET transistor manufactured in accordance with the method of this invention. FIG. 15B—is a cross-sectional, elevational views of the device of FIG. 15A taken along line B-B′ therein. The device is identical except for the dopant which is reversed from P type to N type in the body and in the N-well contact regions. The reference indicia in the drawings are the same as in the previous embodiment.

While this invention has been described in terms of the above specific embodiment(s), those skilled in the art will recognize that the invention can be practiced with modifications within the spirit and scope of the appended claims, which is to say that changes can be made in form and detail, without departing from the spirit and scope of the invention. Accordingly all such changes come within the purview of the present invention and the invention encompasses the subject matter of the following claims.

Having thus described the invention, what is claimed as new and desirable to be secured by Letters Patent is as follows:

1. A semiconductor device including a conductive contact, an FET device, and a switch therebetween comprising:
a semiconductor layer formed over a top surface of a dielectric layer, with said semiconductor layer being divided into a contact region, an FET region having a first thickness, and a switch region having a second thickness less than said first thickness;
a gate dielectric layer formed on an upper surface of said semiconductor layer over said FET region and over said switch region;
an FET device including, a source region, a channel region and a drain region formed in said FET region of said semiconductor layer, and an FET gate electrode formed on top of said gate dielectric layer above said channel;
said switch being juxtaposed with said FET device and including an auxiliary gate electrode formed on said top surface of said gate dielectric layer above said switch region with said auxiliary gate electrode being connected to said FET gate electrode; and
said conductive contact being connected to said contact region formed in said semiconductor layer juxtaposed with said switch region and distal from said FET region.

2. The device of claim 1 wherein:
said switch region is formed in a recess in said upper surface of said semiconductor layer; and surfaces of said recess are covered by said gate dielectric which reaches down into said recess.

3. The device of claim 2 wherein said auxiliary gate electrode reaches down into said recess above said switch region juxtaposed with said FET region.

4. The device of claim 2 wherein:
said auxiliary gate electrode reaches down into said recess above said switch region juxtaposed with said FET region, and
said contact region is juxtaposed with said switch region on an opposite side thereof from said FET region.

5. The device of claim 1, wherein a negative P-well voltage V_{pw} is connected to said conductive contact for supply to said FET region when said switch is closed.

6. The device of claim 1, wherein a positive N-well voltage V_{pw} is connected to said conductive contact for supply to said FET region when said switch is closed.

7. The device of claim 1 wherein STI regions extend through said semiconductor layer to said top surface of said dielectric layer thereby defining a well in said semiconductor layer on either side of said FET region and said switch region.

8. The device of claim 7 wherein:
said switch region is formed in a recess in said top surface of said semiconductor layer;
said recess has sidewalls and a bottom surface covered by said gate dielectric which reaches down into said recess covering said sidewalls and said bottom surface.

9. The device of claim 8 wherein said auxiliary gate electrode reaches down into said recess above said switch region juxtaposed with said FET region.

10. The device of claim 8 wherein:
said auxiliary gate electrode reaches down into said recess above said switch region juxtaposed with said FET region; and
a contact is formed in said contact region juxtaposed with said switch region on the opposite side thereof from said FET region.

11. The device of claim 10, wherein:
a contact is provided to said contact region; and
a well bias voltage V_{pw} is connected to said contact for supply to said FET region when said depletion switch is closed.

12. A method of forming semiconductor device including an FET device a contact, and a switch therebetween comprising:
forming a semiconductor layer over a top surface of a dielectric layer with said semiconductor layer being divided into a contact region, an FET region having a first thickness, and a switch region having a second thickness less than said first thickness;
forming a conformal gate dielectric layer covering said FET region and said switch region;
forming an extended gate electrode over said gate dielectric layer including an FET gate electrode located above said FET region and an auxiliary gate electrode extending from said FET gate electrode over said switch region;
forming an FET device with a source region and a drain region in said FET region juxtaposed with said gate electrode; and
forming a contact reaching into electrical and mechanical contact with said contact region aside from said switch and distal from said FET device;
whereby said auxiliary switch gate is adapted to open and close said switch in said switch region as a function of voltage applied thereto, thereby suppressing subthreshold leakage current.

13. The method of claim 12 wherein said switch region is formed in a recess in said top surface of said semiconductor layer having sidewalls and a bottom surface covered by said gate dielectric which reaches down into said recess covering said sidewalls and said bottom surface.

14. The method of claim 13 wherein said auxiliary gate electrode reaches down into said recess above said switch region juxtaposed with said FET region.

15. The method of claim 13 wherein:
said auxiliary gate electrode reaches down into said recess above said switch region juxtaposed with said FET region, and
a contact region is formed in said semiconductor layer juxtaposed with said switch region on the opposite side thereof from said FET region.

16. The method of claim 15, wherein a conductive contact is provided to said contact region.

17. The method of claim 16, wherein a well bias voltage V_{pw} is connected to said contact for supply to said FET region when said depletion switch is closed.

18. The method of claim 12 wherein STI regions extend through said semiconductor layer to said top surface of said dielectric layer thereby defining a well in said semiconductor layer on either side of said FET region and said switch region.

19. The method of claim 18 wherein said switch region is formed in a recess in said top surface of said semiconductor layer having sidewalls and a bottom surface covered by said gate dielectric which reaches down into said recess covering said sidewalls and said bottom surface.

20. The method of claim 19 wherein said auxiliary gate electrode reaches down into said recess above said switch region juxtaposed with said FET region.
